(19) United States
(12) Patent Application Publication
(10) Pub. No.: US 2019/0326859 A1
(43) Pub. Date: Oct. 24, 2019

(54) Temperature Dependency Compensation

(71) Applicant: Qualcomm Incorporated, San Diego, CA (US)

(72) Inventors: Ahmed Abbas Mohamed Helmy, San Diego, CA (US); Ojas Choksi, San Diego, CA (US)

(21) Appl. No.: 15/961,573

(22) Filed: Apr. 24, 2018

(51) Int. Cl. H03F 1/30; H03F 1/56; H03F 3/193; H03F 3/24

(52) U.S. Cl. CPC H03F 1/30; H03F 1/565; H03F 2200/451; H03F 3/245; H03F 2200/387; H03F 3/193

(57) ABSTRACT

An apparatus is disclosed that implements temperature dependency compensation. In an example aspect, the apparatus includes an amplifier, a transformer, a compensation component, and a bias circuit. The amplifier is configured to amplify a wireless signal to produce an amplified wireless signal. The transformer, which includes an inductor, is coupled to the amplifier and is configured to condition the amplified wireless signal. The compensation component is coupled in series with the inductor. The compensation component includes a compensation transistor that is configured to operate in at least one of a positive temperature-dependence range or a negative temperature-dependence range. The bias circuit includes a bias node that is coupled to the compensation transistor. The bias circuit is configured to cause the compensation transistor to operate in the positive temperature-dependence range or the negative temperature-dependence range.

### TECHNICAL FIELD

This disclosure relates generally to electronic devices and, more specifically, to providing compensation for components that have a performance characteristic that varies with temperature.

### BACKGROUND

Electronic devices include traditional computing devices such as desktop computers, notebook computers, smartphones, wearable devices like a smartwatch, internet servers, and so forth. However, electronic devices also include other types of computing devices such as personal voice assistants, thermostats, automotive electronics, robotics, devices embedded in other machines like refrigerators and industrial tools, Internet of Things (IoT) devices, and so forth. These various electronic devices provide information, entertainment, social interaction, security, safety, productivity, transportation, and other services to human users. Thus, electronic devices play crucial roles in many aspects of modern society.

Many of the services provided by electronic devices in today's interconnected world depend at least partly on electronic communications. Electronic communications can include those exchanged between or among distributed electronic devices using wireless or wired signals that are transmitted over one or more networks, such as the Internet or a cellular network. Thus, electronic communications can be realized by propagating signals between a transmitter and a receiver. With a wireless transceiver, for example, a wireless signal can be transmitted over the air, such as between a smart phone and a base station to provide mobile services. Mobile services include phone calls, video calls, social media interactions, text messaging, watching streamed movies, sharing videos, performing searches, obtaining map information or navigational instructions, and so forth.

Various components that are internal to electronic devices enable signals to be transmitted from, received by, and processed at an electronic device. An example of such a component is an integrated circuit (IC). An integrated circuit chip can facilitate the transmission, reception, or processing of signals by manipulating voltages and currents on the chip. As a result of currents that are flowing due to voltage differences that are created, the components of the integrated circuit generate heat. As the heat accumulates, the heat begins to adversely impact performance of the integrated circuit. For example, at some temperatures, processing errors and even permanent damage to the integrated circuit can occur.

Thus, engineers strive to manage the effects of heat to reduce its adverse impacts on performance. First, engineers attempt to reduce an amount of heat that is generated by using lower voltages or smaller currents. However, there are limits to this approach because some voltage and current has to be used to operate the integrated circuit. Second, engineers attempt to manage the amount of heat that is generated by dispersing the heat. For example, engineers can use heat sinks and fans. Fans, however, are noisy and consume energy, which is a problem for battery-powered devices. Heat sinks are quiet and passive, but heat sinks still occupy some space and are less effective at actually removing heat from a device. Consequently, electrical engineers and other designers of electronic devices continue to look for techniques to manage heat in electronic devices to facilitate electronic communications and other signal processing.

### SUMMARY

Temperature dependency compensation is disclosed as a technique to manage the effects of heat on electronic devices. Some components of an integrated circuit (IC) can have a characteristic that varies based on temperature. This temperature-dependent characteristic of a given component may have a positive dependency on temperature or a negative dependency on temperature. Accordingly, certain described implementations incorporate a compensation component that exhibits an opposite dependency on temperature to compensate for the given component. Consequently, the joint performance of the given component along with the compensation component is less temperature dependent.

In an example aspect, an apparatus is disclosed. The apparatus includes an amplifier, a transformer, a compensation component, and a bias circuit. The amplifier is configured to amplify a wireless signal to produce an amplified wireless signal. The transformer, which includes an inductor, is coupled to the amplifier and is configured to condition the amplified wireless signal. The compensation component is coupled in series with the inductor. The compensation component includes a compensation transistor that is configured to operate in at least one of a positive temperature-dependence range or a negative temperature-dependence range. The bias circuit includes a bias node that is coupled to the compensation transistor. The bias circuit is configured to cause the compensation transistor to operate in the positive temperature-dependence range or the negative temperature-dependence range.

In an example aspect, a wireless transceiver with temperature dependency compensation is disclosed. The wireless transceiver includes a transformer, a compensation transistor, and a bias circuit. The transformer includes an inductor having a first terminal. The compensation transistor is coupled in series with the inductor via the first terminal, and the compensation transistor includes a gate terminal. The bias circuit is coupled to the gate terminal of the compensation transistor. The bias circuit includes a resistor coupled to a power rail and a bias transistor coupled to the resistor. The bias circuit also includes a current source coupled to the bias transistor and a bias node coupled to the gate terminal of the compensation transistor.

In an example aspect, a system is disclosed. The system includes an amplifier and a transformer that is coupled to the amplifier. The transformer includes an inductor having a temperature-dependent resistive characteristic. The system also includes compensation means for counteracting the temperature-dependent resistive characteristic of the inductor, with the compensation means coupled to the inductor. The system further includes bias means for biasing the compensation means based on a temperature, with the bias means coupled to the compensation means.

In an example aspect, a method for compensating for a temperature dependency of a circuit is disclosed. The method includes amplifying a wireless signal to produce an amplified wireless signal. The method also includes propagating the amplified wireless signal through an inductor of a transformer to produce a conditioned wireless signal and propagating the conditioned wireless signal through a compensation transistor. The method additionally includes generating a gate bias voltage that is dependent on a temperature and routing the gate bias voltage to the compensation transistor. The method further includes biasing the compensation transistor to operate in a negative temperature-dependence range responsive to the routing.

### BRIEF DESCRIPTION OF DRAWINGS

FIG. 1 illustrates an example environment that includes a wireless transceiver in which temperature dependency compensation can be implemented.

FIG. 2 illustrates an example wireless transceiver including a receive chain and a transmit chain that each have a transformer and temperature compensation circuitry to implement temperature dependency compensation.

FIG. 3 illustrates an example transformer including an inductor and example temperature compensation circuitry including a compensation component and a bias circuit.

FIG. 4 illustrates example performance aspects for an inductor alone and as part of a transformer.

FIG. 5 illustrates example performance aspects for a compensation component.

FIG. 6 illustrates example compensation components and an example bias circuit for the compensation components.

FIG. 7 illustrates an example bias circuit like the one of FIG. 6, with the bias circuit depicting example implementations for a resistor and a current source.

FIG. 8 illustrates an example capacitor that includes temperature compensation circuitry and that can be incorporated into an inductor-capacitor tank as part of a transformer.

FIG. 9 is a flow diagram illustrating an example process for temperature dependency compensation.

### DETAILED DESCRIPTION

To provide today's digital services, many electronic devices communicate via wireless signals using a transceiver. A transceiver is used to transmit or receive a wireless signal and includes a transmit chain and a receive chain. Each transmit chain or receive chain may include at least one transformer that has a primary coil and a secondary coil, with each coil implemented as an inductor. A transformer can condition a signal that is propagating through a transmit or receive chain in different manners. For example, a transformer can change a voltage level of a signal that is propagated from the primary coil to the secondary coil or can physically isolate two portions of a circuit. Additionally, a transformer can be combined with a capacitive component to create an inductor-capacitor tank that is used to tune the propagating signal.

For reliable and precise operation of an electronic device, a transceiver is typically expected to operate over a wide temperature range, such as −40° C. to +125° C. Across this wide temperature range, the transceiver is intended to maintain consistently good performance—e.g., in terms of signal-to-noise ratio (SNR), dynamic range, and bit error rate (BER). Of the multiple different components included in a transceiver, a component that typically exhibits appreciable dependence on temperature is the transformer. This temperature dependency of the transformer causes a gain of the transformer to vary across different temperatures, which adversely impacts operation of the overall transceiver. For example, a gain of the transceiver becomes dependent on the temperature due to the transformer, which renders the performance of the transceiver unpredictable, or at least variable.

A transformer's ability to provide a good gain can be quantified by a quality factor (Q). A loaded quality factor of a transformer depends at least partially on the quality factor (e.g., the losses) of the transformer itself and on a quality factor of an associated capacitor used for tuning the transformer. The respective quality factors of the transformer and tuning capacitor are both sensitive to temperature. This temperature sensitivity affects the transformer's gain and noise figure (NF) as the temperature changes and further leads to SNR degradation. As a numerical example, a quality factor (Q) of a transformer can vary 40% over the temperature range of −40° C. to +125° C.

If the expected operational temperature range were narrowed, the quality factor variance would narrow as well. However, ambient temperatures on the earth can frequently vary from below 0° C. to over 100° C. Moreover, the electrical activity of the device itself generates heat. Mechanical approaches to handling this generated heat include heat sinks and fans. These approaches are large, noisy, energy-consuming, and/or inadequate. Given the earth's ambient temperature range as well as device self-heating, it is apparent that some electronic devices will be subjected to a wide temperature range during operation.

Thus, it is also apparent that transformers in the transceivers of electronic devices will be exposed to widely-varying temperatures, which produces a variance in the Q factor of the transformer. To address this variance in the Q factor of a transformer, example implementations that are described herein can compensate for a transformer's sensitivity to temperature. To do so, another component is coupled to the transformer that has an opposite sensitivity to temperature. This opposite sensitivity to temperature can be approximately equal in magnitude. For example, a real portion of an impedance of a transformer, e.g.—a resistance of an inductor, has a positive temperature dependency. Thus, some described implementations compensate for a temperature dependency of a transformer by including in series with the transformer a component that has a negative temperature dependency with a substantially equivalent resistance value.

In example implementations, a transformer of a wireless transceiver includes an inductor. The inductor has an inductive reactance characteristic and a resistive characteristic. The resistive characteristic has a positive temperature dependency. In other words, a resistance of the inductor increases as temperature increases. Counteracting this positive temperature dependency of the inductor can increase the Q factor of the transformer. To counteract the positive temperature dependency of the inductor, a compensation component of temperature compensation circuitry is coupled in series with the inductor. The compensation component has a resistive characteristic with a negative temperature dependency. In other words, a resistance of the compensation component decreases as temperature increases.

In operation, the negative temperature dependency of the compensation component can counteract (e.g., at least partially balance, work in opposition to, reduce an effect of) the positive temperature dependency of the inductor. In this manner, a joint temperature dependency of the combination of the inductor and the compensation component produces a higher Q for the transformer as compared to the inductor alone. This higher Q for the transformer results in a higher Q for the wireless transceiver in which the transformer is included. Consequently, signals can be propagated through, and conditioned by, the transformer with less negative effect.

In some implementations, the compensation component is implemented as a compensation transistor, which can operate as a switch and has a variable resistive characteristic. The variable resistive characteristic can have a positive temperature dependency or a negative temperature dependency responsive to how the compensation transistor is biased. Accordingly, the temperature compensation circuitry can include, in addition to a compensation transistor, a bias circuit to bias the compensation transistor into a negative temperature dependence range. The bias circuit may include a bias transistor that comprises, for example, a replica of the compensation transistor. The bias transistor is used to establish a desired gate bias voltage across different temperatures using a feedback mechanism that is described herein below. Thus, a compensation transistor under the control of a bias circuit can compensate for a temperature-sensitive component, such as an inductor of a transformer.

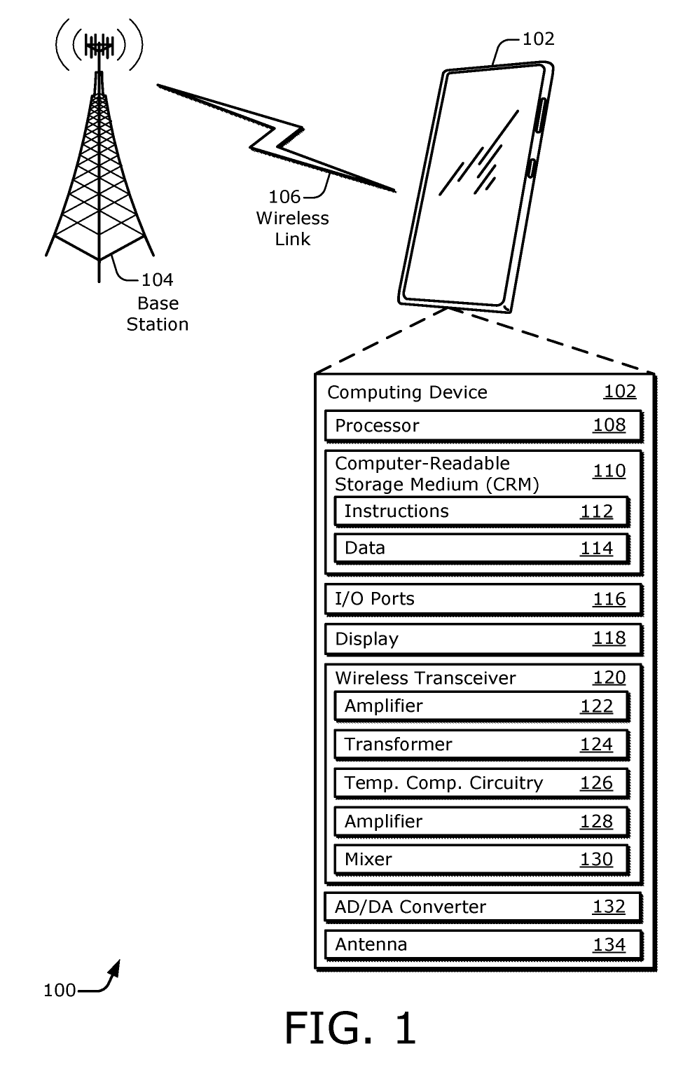

FIG. 1 illustrates an example environment 100 that includes a wireless transceiver 120 in which temperature dependency compensation can be implemented. The example environment 100 includes a computing device 102 that communicates with a base station 104 through a wireless communication link 106 (wireless link 106). In this example, the computing device 102 is implemented as a smart phone. However, the computing device 102 may be implemented as any suitable computing or other electronic device, such as a modem, cellular base station, broadband router, access point, cellular phone, gaming device, navigation device, media device, laptop computer, desktop computer, tablet computer, server, network-attached storage (NAS) device, smart appliance, vehicle-based communication system, Internet of Things (IoT) device, and so forth.

The base station 104 communicates with the computing device 102 via the wireless link 106, which may be implemented as any suitable type of wireless link. Although depicted as a base station tower of a cellular radio network, the base station 104 may represent or be implemented as another device, such as a satellite, cable television head-end, terrestrial television broadcast tower, access point, peer-to-peer device, mesh network node, fiber optic line, electronic device generally, and so forth. Hence, the computing device 102 may communicate with the base station 104 or another device via a wired connection, a wireless connection, or a combination thereof.

The wireless link 106 extends between the computing device 102 and the base station 104. The wireless link 106 can include a downlink of data or control information communicated from the base station 104 to the computing device 102 and an uplink of other data or control information communicated from the computing device 102 to the base station 104. The wireless link 106 may be implemented using any suitable communication protocol or standard, such as 3rd Generation Partnership Project Long-Term Evolution (3GPP LTE), IEEE 802.11, IEEE 802.16, Bluetooth™, and so forth.

As shown, the computing device 102 includes a processor 108 and a computer-readable storage medium 110 (CRM 110). The processor 108 may include any type of processor, such as an application processor or multi-core processor, that is configured to execute processor-executable instructions (e.g., code) stored by the CRM 110. The CRM 110 may include any suitable type of data storage media, such as volatile memory (e.g., random access memory (RAM)), non-volatile memory (e.g., Flash memory), optical media, magnetic media (e.g., disk or tape), and so forth. In the context of this disclosure, the CRM 110 is implemented to store instructions 112, data 114, and other information of the computing device 102, and thus does not include transitory propagating signals or carrier waves.

The computing device 102 may also include input/output ports 116 (I/O ports 116) or a display 118. The I/O ports 116 enable data exchanges or interactions with other devices, networks, or users. The I/O ports 116 may include serial ports (e.g., universal serial bus (USB) ports), parallel ports, audio ports, infrared (IR) ports, and so forth. The display 118 presents graphics of the computing device 102, such as a user interface associated with an operating system, program, or application. Alternatively or additionally, the display 118 may be implemented as a display port or virtual interface through which graphical content of the computing device 102 is communicated or presented.

For communication purposes, the computing device 102 also includes a wireless transceiver 120 and an antenna 134. The wireless transceiver 120 provides connectivity to respective networks and other electronic devices connected therewith. Additionally or alternatively, the computing device 102 may include a wired transceiver, such as an Ethernet or fiber optic interface for communicating over a personal or local network, an intranet, or the Internet. The wireless transceiver 120 may facilitate communication over any suitable type of wireless network, such as a wireless local area network (LAN) (WLAN), a peer-to-peer (P2P) network, a mesh network, a cellular network, a wireless wide-area-network (WWAN), or a wireless personal-area-network (WPAN). In the context of the example environment 100, the wireless transceiver 120 enables the computing device 102 to communicate with the base station 104 and networks connected therewith.

The wireless transceiver 120 includes circuitry and logic for transmitting or receiving a communication signal for at least one communication frequency band. In operation, the wireless transceiver 120 can implement at least one, e.g., radio frequency (RF) transceiver to process data and/or signals associated with communicating data of the computing device 102 via the antenna 134. Although not explicitly shown, the wireless transceiver 120 may include at least one baseband modem. The baseband modem may be implemented as a system on-chip (SoC) that provides a digital communication interface for data, voice, messaging, and other applications of the computing device 102. The baseband modem may also include baseband circuitry to perform high-rate sampling processes that can include analog-to-digital conversion (ADC), digital-to-analog conversion (DAC), gain correction, skew correction, frequency translation, and so forth.

Generally, the wireless transceiver 120 can include filters, switches, amplifiers, mixers, and so forth for routing and conditioning signals that are transmitted or received via the antenna 134. As shown, the wireless transceiver 120 includes at least one amplifier 122, at least one transformer 124, temperature compensation circuitry 126, at least one amplifier 128, and at least one mixer 130. In some implementations, the amplifier 122 and the amplifier 128 are coupled to opposite sides of the transformer 124. The amplifier 122 is coupled to the antenna 134. Thus, the amplifier 122 can couple a wireless signal to or from the antenna 134 in addition to increasing a strength of the signal. The transformer 124 provides a physical or electrical separation between the amplifier 122 and other circuitry of the wireless transceiver 120 and also conditions a signal propagating through the transformer 124. The amplifier 128, like the amplifier 122, reinforces a strength of a propagating signal. The amplifier 128, however, may be coupled to a modem (not shown) or an AD/DA converter 132 as described below.

The wireless transceiver 120 can further perform frequency conversion using a synthesized signal and the mixer 130, which may include an upconverter and/or a downconverter that performs frequency conversion in a single conversion step, or through multiple conversion steps. The wireless transceiver 120 may also include logic (not shown) to perform in-phase/quadrature (I/Q) operations, such as synthesis, encoding, modulation, demodulation, and decoding using a synthesized signal. At least one AD/DA converter 132 is coupled to the wireless transceiver 120. The AD/DA converter 132 performs analog-to-digital conversion (ADC) or digital-to-analog conversion (DAC).

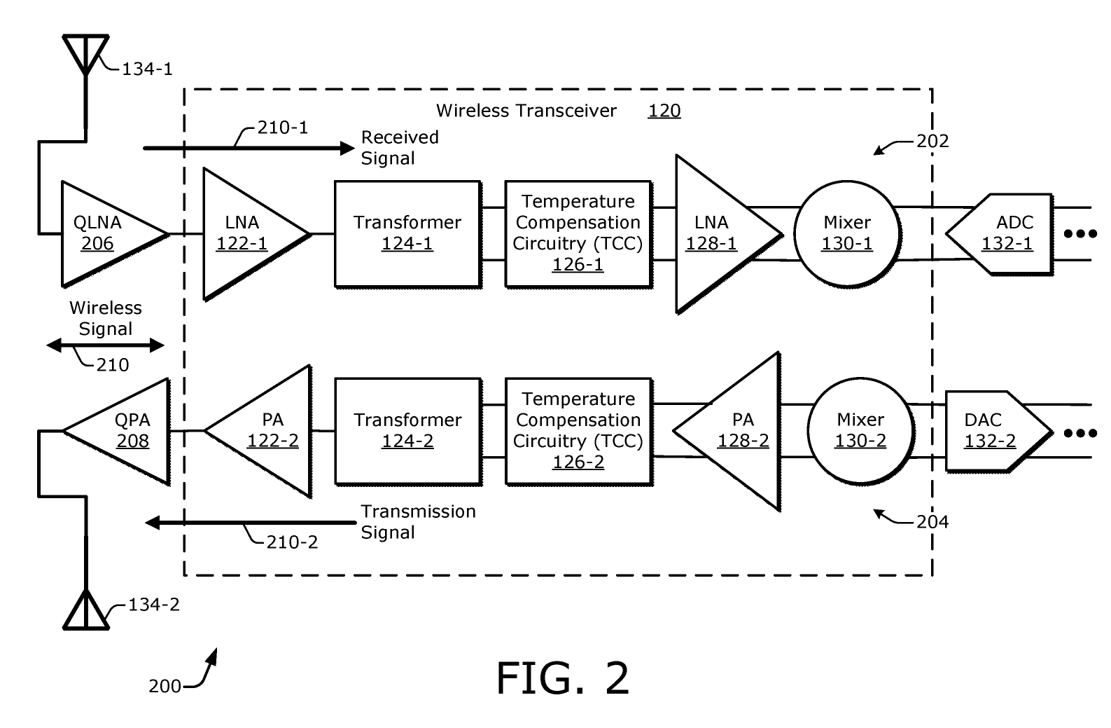

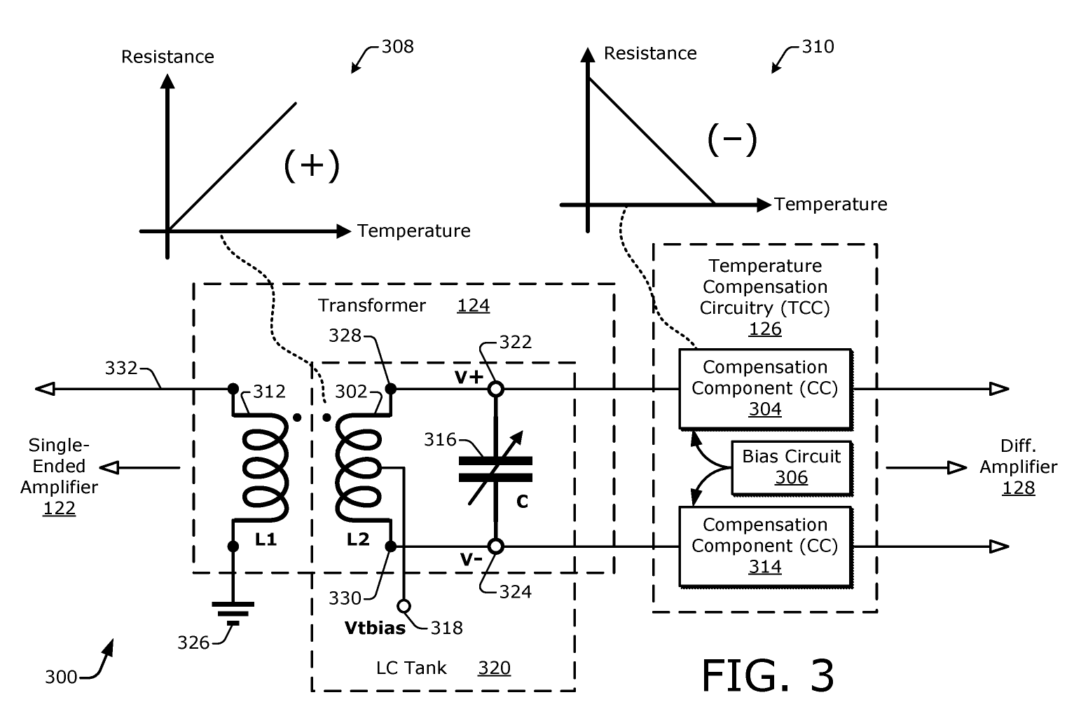

In some cases, components of the wireless transceiver 120 are implemented as at least partially separate receiver and transmitter entities. Additionally or alternatively, the wireless transceiver 120 can be realized using multiple or different sections to implement respective receiving and transmitting operations (e.g., using separate transmit and receive chains). Example operations of, as well as interactions between, the illustrated components of the wireless transceiver 120 are described with reference to FIG. 2. The description of FIG. 3 focuses on example implementations of the transformer 124 and the temperature compensation circuitry 126. As described herein, the wireless transceiver 120 can provide a measure of compensation for a temperature sensitivity of the transformer 124 using the temperature compensation circuitry 126.

FIG. 2 illustrates generally at 200 an example wireless transceiver 120 including a receive chain 202 and a transmit chain 204 that each have a transformer 124 and temperature compensation circuitry 126 to implement temperature dependency compensation. The example receive chain 202 is depicted in the upper half of the wireless transceiver 120, and the example transmit chain 204 is depicted in the lower half. Each of the receive chain 202 and the transmit chain 204 is coupled to at least one antenna 134 to enable a wireless signal 210 to be received or transmitted, respectively. The wireless signal 210 can include a received signal 210-1 or a transmission signal 210-2. As illustrated, the receive chain 202 is coupled to an antenna 134-1 via a quadrature low-noise amplifier 206 (QLNA 206). The transmit chain 204 is coupled to an antenna 134-2 via a quadrature power amplifier 208 (QPA 208).

Although the receive chain 202 and the transmit chain 204 are shown coupled to two different antennas 134-1 and 134-2, the chains may instead be coupled to multiple antennas, to the same one or more antennas, to at least one antenna array, and so forth. Further, although a particular set of components in a particular order are illustrated in FIG. 2 and described herein, each of the receive chain 202 or the transmit chain 204 may include different components, different combinations of components, different orders of components, alternative interconnections, and so forth. Additionally, the receive chain 202 and the transmit chain 204 may share one or more components.

In example implementations, the receive chain 202 processes a received signal 210-1 that is obtained via the antenna 134-1 and the quadrature low-noise amplifier 206. The receive chain 202 includes, from left-to-right, a low-noise amplifier 122-1 (LNA 122-1), a transformer 124-1, temperature compensation circuitry 126-1 (TCC), a low-noise amplifier 128-1 (LNA 128-1), a mixer 130-1, and an analog-to-digital converter 132-1 (ADC 132-1). As indicated by the ellipses (“ . . . ”) depicted on the right of FIG. 2, the receive chain 202 can continue processing the received signal 210-1, e.g., as part of baseband circuitry (not explicitly indicated). The low-noise amplifier 122-1 can be implemented as a single-ended low-noise amplifier or as a differential low-noise amplifier, or as another type of amplifier. Similarly, the low-noise amplifier 128-1 can be implemented as a single-ended low-noise amplifier or as a differential low-noise amplifier, or as another type of amplifier.

In an example operation, the low-noise amplifier 122-1 amplifies the received signal 210-1 and provides the amplified received signal 210-1 to the transformer 124-1. Here, the transformer 124-1 provides physical separation between different portions of the wireless transceiver 120 and in some implementations transforms the single-ended received signal 210-1 into a double-ended, differential received signal 210-1. The transformer 124-1 can further condition the received signal 210-1, such as by altering a voltage level of the received signal 210-1, tuning the received signal 210-1 (e.g., using an inductor and a capacitor), and so forth. In the receive chain 202, one transformer 124-1 is explicitly shown. However, the receive chain 202 may include multiple transformers. For example, multiple transformers can be coupled together in parallel with each other to support receiving operations for a broadband architecture. With three transformers, for instance, each respective transformer can condition signals for a different frequency band, such as low, mid, and high bands. In a similar manner, multiple parallel transformers can be implemented in the transmit chain 204 to support transmitting operations for a broadband architecture. As described with reference to FIG. 3 et seq., the temperature compensation circuitry 126-1 can provide compensation for signal degradation or alteration caused by the transformer 124-1 due to a temperature dependency of at least one component thereof, such as at least one inductor.

The transformer 124-1 passes the conditioned, differential received signal 210-1 to the low-noise amplifier 128-1 to be amplified after conditioning by the transformer 124-1. Although the low-noise amplifier 128-1 in this example is depicted as having a differential configuration, the low-noise amplifier 128-1 may have an alternative configuration, such as a single-ended configuration. After the low-noise amplifier 128-1 increases the signal strength, the mixer 130-1 mixes a reference signal produced by a local oscillator (not shown) with the amplified received signal 210-1 to down-convert the received signal 210-1 from one frequency to a lower frequency, such as from a radio frequency (RF) to an intermediate frequency (IF) or from an intermediate frequency to a baseband (BB) frequency. The down-converted received signal 210-1 is passed out of the wireless transceiver 120 to the analog-to-digital converter 132-1, which converts the analog information encoded in the received signal 210-1 into digital information. The analog-to-digital converter 132-1 can then forward the received signal 210-1 to additional baseband processor or modem components for further processing.

In example implementations, the transmit chain 204 operates in manner that is analogous to that of the receive chain 202, but in an opposite direction on a transmission signal 210-2. The transmit chain 204 includes, from right-to-left, a digital-to-analog converter 132-2 (DAC 132-2), a mixer 130-2, a power amplifier 128-2 (PA 128-2), temperature compensation circuitry 126-2, a transformer 124-2, and a power amplifier 122-2 (PA 122-2). The power amplifier 128-2 can be implemented as a single-ended power amplifier or as a differential power amplifier, or as another type of amplifier. Similarly, the power amplifier 122-2 can be implemented as a single-ended power amplifier or as a differential power amplifier, or as another type of amplifier. In an example operation, the digital-to-analog converter 132-2 receives an analog version of the transmission signal 210-2 from baseband circuitry and converts the transmission signal 210-2 to a digital version. The mixer 130-2 upconverts the digital transmission signal 210-2, and the power amplifier 128-2 amplifies the upconverted transmission signal 210-2 to produce an amplified transmission signal 210-2.

The amplified transmission signal 210-2 is applied in a differential mode to the transformer 124-2. The transformer 124-2 converts the transmission signal 210-2 from the differential mode to a single-ended mode and can also condition the transmission signal 210-2. As described below with reference to FIG. 3 et seq., the temperature compensation circuitry 126-2 can provide compensation for signal degradation or alteration caused by the transformer 124-2 due to a temperature dependency of at least one component thereof, such as at least one inductor. The transformer 124-2 provides the conditioned, single-ended transmission signal 210-2 to the power amplifier 122-2. After amplification, the power amplifier 122-2 provides an amplified transmission signal 210-2 to the quadrature power amplifier 208 for subsequent electromagnetic emanation from the antenna 134-2. Although the transformer 124-1 and the transformer 124-2 are each described and depicted as converting a signal between a single-ended mode and a differential mode, either or both transformers may alternatively be single-ended or differential on both sides. Further, the temperature compensation circuitry 126-1 or the temperature compensation circuitry 126-1 (or both) can alternatively be implemented on a single-ended side of a transformer 124.

FIG. 3 illustrates generally at 300 an example transformer 124 including an inductor 302 and example temperature compensation circuitry 126. The temperature compensation circuitry 126 includes a compensation component 304 and a bias circuit 306. The transformer 124 can correspond to the transformer 124-1 of the receive chain 202 or the transformer 124-2 of the transmit chain 204 (all of FIG. 2). As indicated at the left and right edges of FIG. 3, the illustrated transformer 124 and the temperature compensation circuitry 126 can be coupled between, for example, an amplifier 122 and an amplifier 128. However, the transformer 124 or the temperature compensation circuitry 126 can be incorporated into a receive chain or a transmit chain at a different position.

The temperature compensation circuitry 126 is depicted as being included at a differential side of the transformer 124. However, the temperature compensation circuitry 126 can additionally or alternatively be included on a single-ended side of the transformer 124. Temperature compensation circuitry 126 as described herein can also be employed with a transformer that is single-ended or double-ended on both sides. Further, temperature dependency compensation can be implemented with inductors in other scenarios besides those that are part of a transformer or with other temperature-dependent circuit components besides inductors.

In example implementations, the transformer 124 includes an inductor 312 (L1) that is part of a first coil of a primary winding and an inductor 302 (L2) that is part of a second coil of a secondary winding. With the single-ended side, the inductor 312 is coupled between a signal line 332 and an equipotential, such as a ground node 326. The inductor 302 includes a first terminal 328 and a second terminal 330. On the differential side, the inductor 302 is coupled between a plus voltage (V+) line with a plus node 322 and a minus voltage (V−) line with a minus node 324. As shown, the first terminal 328 is coupled to the plus node 322, and the second terminal 330 is coupled to the minus node 324. The inductor 302 can be biased via an intermediate tap using a transformer bias voltage (Vtbias) applied at a tap node 318. Although a particular mutual inductance polarity for the transformer 124 is indicated using the dot notation convention, the transformer 124 may be implemented with a different mutual inductance polarity.

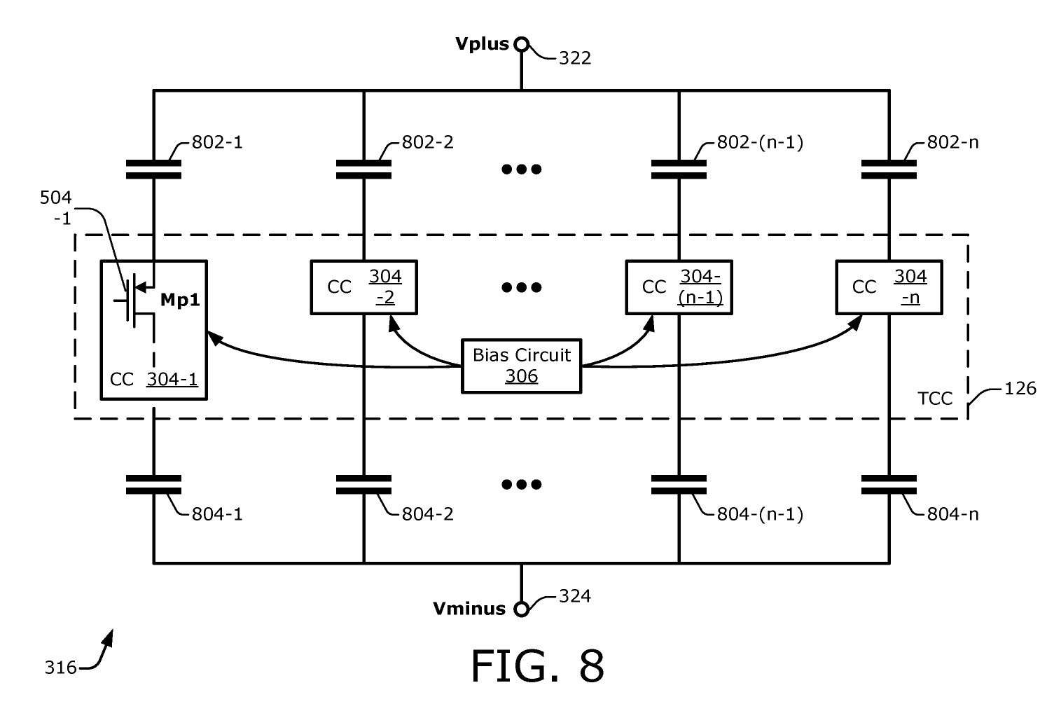

In some implementations, the transformer 124 can include an inductive-capacitive tank 320 (LC Tank 320). The inductive-capacitive tank 320 is configured to tune a frequency of a signal output by the differential side of the transformer 124. The inductive-capacitive tank 320 includes the inductor 302 and a capacitor 316. The capacitor 316 (C) can be implemented as an adjustable capacitor. As shown in FIG. 3, the capacitor 316 can be coupled in parallel with the inductor 302 between the first terminal 328 and the second terminal 330 at the plus node 322 and the minus node 324, respectively. Further, temperature dependency compensation as described herein can be implemented as part of the capacitor 316 or the inductive-capacitive tank 320 to account for temperature sensitivity of the capacitive component(s). Example implementations that incorporate temperature compensation circuitry 126 with an adjustable capacitor 316 having a variable capacitance are described below with reference to FIG. 8.

In example implementations, the temperature compensation circuitry 126 (TCC) includes at least one compensation component 304 (CC) and at least one bias circuit 306. The temperature compensation circuitry 126 is coupled to the transformer 124. As shown in FIG. 2, the temperature compensation circuitry 126 can be coupled in series with the transformer 124 along a receive chain 202 or a transmit chain 204, on either or both sides of the transformer 124. For example, a compensation component 304 can be coupled between the first terminal 328 of the inductor 302 (e.g., at the plus node 322) and an amplifier, such as the amplifier 128. Also, another compensation component 314 can be coupled between the second terminal 330 of the inductor 302 (e.g., at the minus node 324) and the amplifier. In some implementations, the bias circuit 306 controls the compensation components 304 and 314 to place each in an operational mode to compensate for a temperature dependency of the inductor 302.

The inductor 302 includes an inductive reactance characteristic and a resistive characteristic. The resistive characteristic, or resistance, has a positive temperature dependency as depicted in a graph 308. The graph 308 has an abscissa or x-axis that represents temperature and an ordinate or y-axis that represents resistance. As indicated by the graph 308, a resistance value of the resistance characteristic of the inductor 302 increases as a temperature thereof increases. This temperature dependency of the inductor 302 can lower a Q factor of the transformer 124. Thus, counteracting this positive temperature dependency of the inductor 302 can increase the Q factor of the transformer 124. To do so, the compensation component 304 or the compensation component 314 of the temperature compensation circuitry 126 is or are coupled to the inductor 302. For instance, at least the compensation component 304 can be coupled in series with the inductor 302.

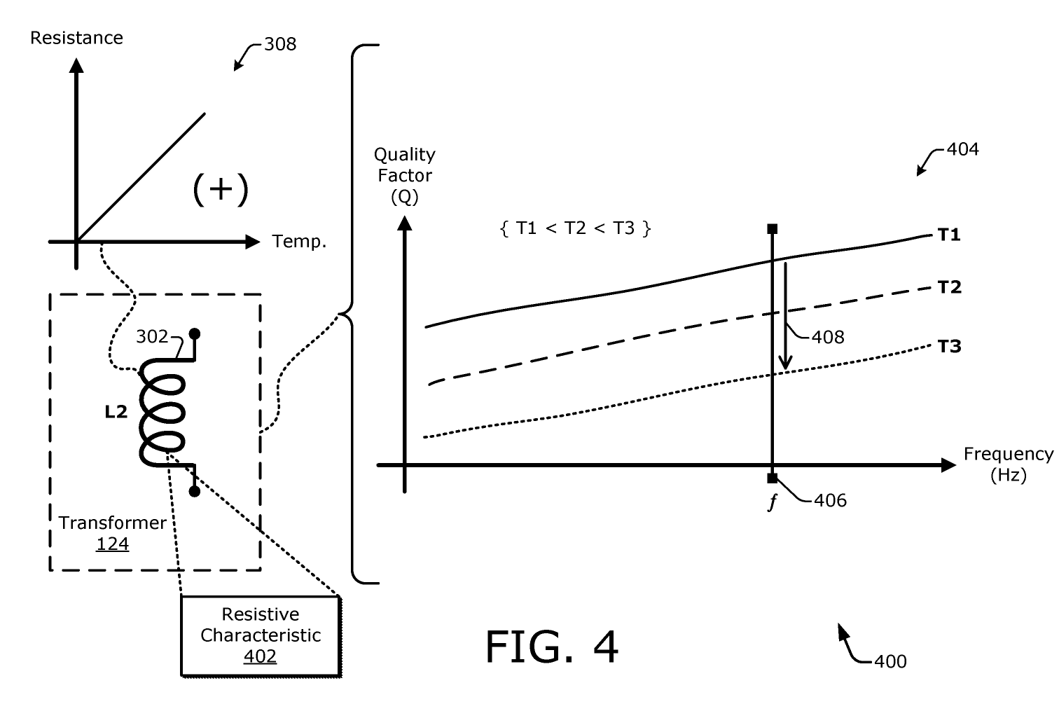

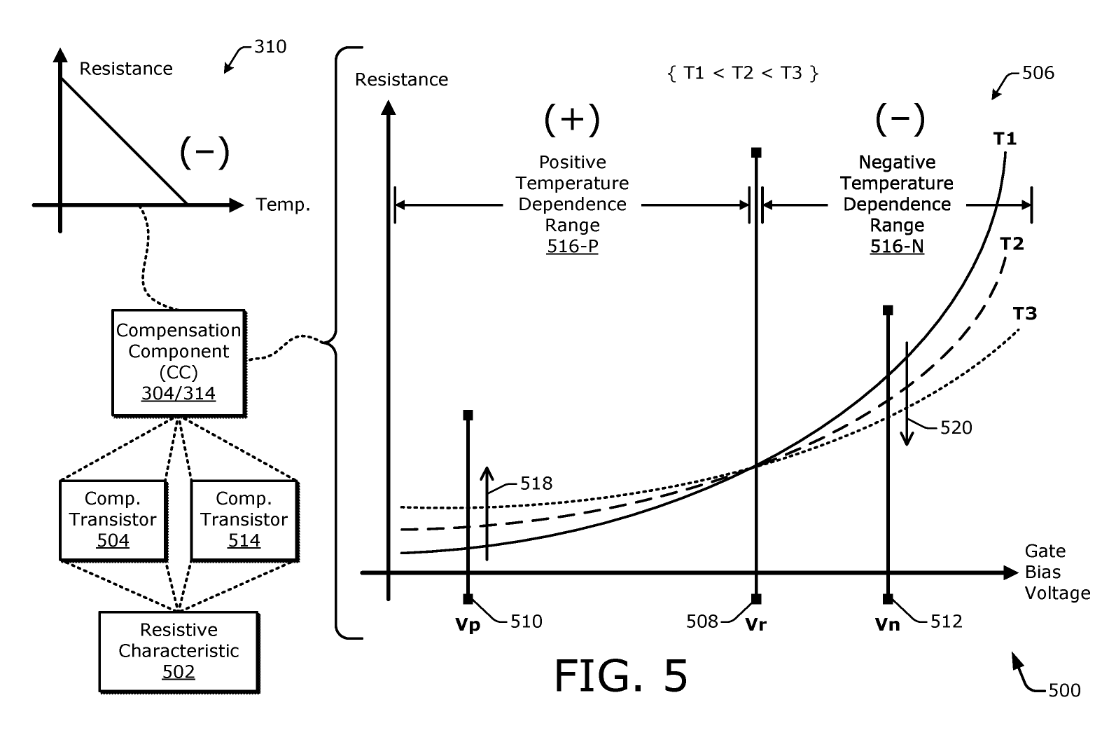

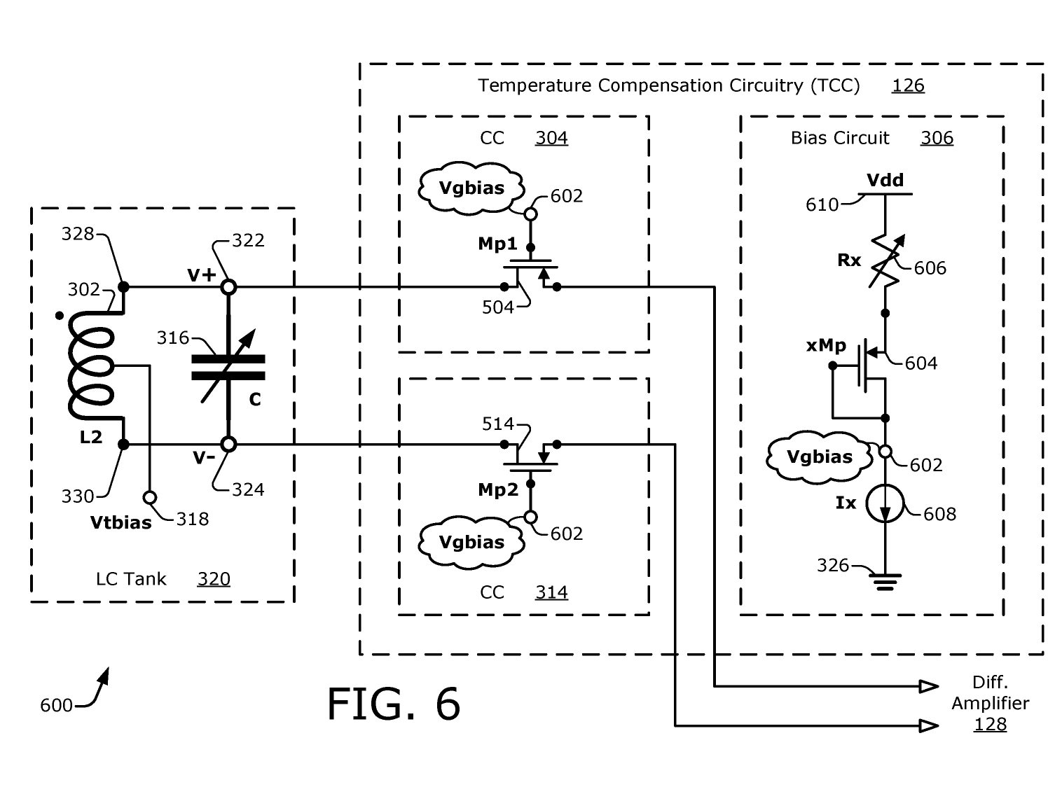

In an example operation, the compensation component 304 has a resistive characteristic with a negative temperature dependency as depicted in a graph 310. The graph 310 has an abscissa or x-axis that represents temperature and an ordinate or y-axis that represents resistance. As indicated by the graph 310, a resistance value of the resistive characteristic of the compensation component 304 decreases as a temperature thereof increases. The inverse or opposite temperature dependence of the compensation component 304 can therefore compensate for the temperature dependence of the inductor 302. Thus, the compensation component 304 or 314 can provide a compensation mechanism for counteracting the temperature-dependent resistive characteristic of the inductor 302. The bias circuit 306 can provide a bias mechanism for biasing the compensation component 304 or 314 based on a temperature, as described below with reference to FIG. 6. The opposite temperature dependencies are described qualitatively below with reference to the graphs depicted in FIGS. 4 and 5. Although temperature dependency compensation is described herein using the compensation component 304, the principles thereof are also applicable to the compensation component 314. Further, a given implementation may include the compensation component 304 coupled to one end of the inductor 302 (e.g., without including the compensation component 314), the compensation component 314 coupled to another end of the inductor 302 (e.g., without including the compensation component 304), or both the compensation component 304 and the compensation component 314 coupled to different ends of the inductor 302.

FIG. 4 illustrates generally at 400 example performance aspects of an inductor 302 alone and as part of a transformer 124. The inductor 302 includes an inductive reactance characteristic (not shown) and a resistive characteristic 402. The graph 308 depicts how this resistance varies with temperature. As shown in the graph 308, the resistance value of the resistive characteristic 402 has a positive dependence on temperature. This positive dependency on temperature of the inductor 302 causes changes in the quality factor Q of the transformer 124.

An example effect on the quality factor Q of the transformer 124 by the temperature dependency of the inductor 302 is depicted in a graph 404 on the right. The graph 404 has an abscissa or x-axis that represents frequency (Hz) of a signal (e.g., the wireless signal 210 of FIG. 2) that is propagating through the transformer 124. The graph 404 also has an ordinate or y-axis that represents a quality factor Q of the transformer 124. In an example scenario, the depicted portion of the three curves in the graph 404 can extend from approximately 500 to 700 MHz along the frequency dimension. For the primary side of the transformer 124 (e.g., the inductor 312 of FIG. 3), the depicted portion of the three curves can extend from approximately 3.0 to 6.2 along the quality factor (Q) dimension. For the secondary side of the transformer 124 (e.g., the inductor 302), the depicted portion of the three curves can extend from approximately 4.5 to 9.0 along the quality factor (Q) dimension.

Three roughly parallel curves are shown in the graph 404. The three curves are indicated by “T1,” “T2,” and “T3” for three different respective temperatures: lower, mid-level, and higher. The curve for T1 has a solid line; the curve for T2 has a large-dashed line; and the curve for T3 has a small-dashed line. Each curve represents a graph of frequency versus quality factor for the transformer 124 at a different temperature. Each curve gradually increases from left to right. Thus, at any given temperature, the quality factor of the transformer 124 increases with increasing frequency.

For the graph 404, the temperature T1 is less than that of the temperature T2, and the temperature T2 is less than that of the temperature T3. The curve for T1 is above the curve T2, and the curve for T2 is above the curve for T3. Thus, the quality factor (Q) at the lower temperature T1 is generally higher than the quality factor at the mid-level temperature T2. Similarly, the quality factor at the mid-level temperature T2 is generally higher than the quality factor at the higher temperature T3. Thus, at any given frequency 406 (f), the quality factor for the transformer 124 decreases as the temperature increases, as indicated by an arrow 408.

In other words, as the temperature increases from T1 to T2, and from T2 to T3, the performance of the transformer 124 decreases as represented by a decreasing quality factor. This quality factor reduction is caused, at least partially, by the temperature dependency of the inductor 302. To counteract or offset this temperature dependency of the inductor 302, another component with an opposite temperature dependency can be coupled in series with the inductor 302. Characteristics of such a compensation component are described below with reference to FIG. 5.

FIG. 5 illustrates generally at 500 example performance aspects for a compensation component 304 or 314. In example implementations, the compensation component 304 is realized as a compensation transistor 504, and the compensation component 314 is realized as a compensation transistor 514. Each of the compensation transistors 504 and 514 includes a resistive characteristic 502. The graph 310 depicts how the associated resistance of the compensation transistor can vary with temperature. As shown in the graph 310, the resistance value of the resistive characteristic 502 has a negative dependence on temperature. Thus, the resistance value decreases as the temperature increases. However, the compensation transistor 504 or 514 may not automatically exhibit this negative temperature dependency. Instead, the compensation transistor 504 or 514 may be placed into an operational mode that produces such a negative temperature dependency. The description herein below refers to the compensation transistor 504, but the described principles may also be applied to the compensation transistor 514.

Different modes of operation for the compensation transistor 504, from a temperature-dependency perspective, can be achieved by biasing the compensation transistor 504 into different temperature-dependency ranges. Examples of two different temperature-dependency ranges for the compensation transistor 504 are depicted in a graph 506 on the right. The graph 506 has an abscissa or x-axis that represents a gate bias voltage of the compensation transistor 504. The graph 506 also has an ordinate or y-axis that represents a resistance that can result from the various gate bias voltages applied to the compensation transistor 504. In an example scenario, the depicted portion of the three curves in the graph 506 can extend from approximately 0 to 380 millivolts (mV) along the gate-bias voltage dimension. The depicted portion of the three curves can extend from approximately 120 to 380 milliohms (me).

In the graph 506, the three curves are indicated by “T1,” “T2,” and “T3” for three different respective temperatures: lower, mid-level, and higher. Thus, the lower temperature T1 is less than that of the mid-level temperature T2, and the mid-level temperature T2 is less than that of the higher temperature T3. The curve for T1 has a solid line; the curve for T2 has a large-dashed line; and the curve for T3 has a small-dashed line. Each curve represents a graph of gate bias voltage versus resistance for the compensation transistor 504 at a different temperature. Each curve increases relatively dramatically (e.g., exponentially) from left to right. Thus, at any given temperature, the resistance of the compensation transistor 504 increases with increasing gate bias voltage. The increase in resistance value per unit of gate-bias-voltage increase is greater as the gate bias voltage increases on the right side of the graph 506.

There are multiple temperature-dependency ranges 516 for the operation of the compensation transistor 504. Whether a curve for one temperature is above or below a curve for another temperature depends on which temperature-dependency range 516 the compensation transistor 504 is currently biased to operate in. On the left of the graph 506, a positive temperature-dependence range 516-P for the compensation transistor 504 is shown. On the right of the graph 506, a negative temperature-dependence range 516-N is shown. The two ranges 516 are separated by a range-demarcating gate bias voltage 508 (Vr).

In the positive temperature-dependence range 516-P, the curve for T3 is above the curve T2, and the curve for T2 is above the curve for T1. These curve relationships indicate that the resistance at the higher temperature T3 is generally higher than the resistance at the mid-level temperature T2 within the positive temperature-dependence range 516-P. Similarly, the resistance at the mid-level temperature T2 is generally higher than the resistance at the lower temperature T1. Thus, at any given gate bias voltage within the positive temperature-dependence range 516-P, such as at a particular voltage 510 (Vp), the resistance of the compensation transistor 504 increases as the temperature increases, as indicated by an arrow 518.

In the negative temperature-dependence range 516-N, the curve for T1 is above the curve T2, and the curve for T2 is above the curve for T3. This indicates that the resistance at the lower temperature T1 is generally higher than the resistance at the mid-level temperature T2 within the negative temperature-dependence range 516-N. Similarly, the resistance at the mid-level temperature T2 is generally higher than the resistance at the higher temperature T3. Thus, at any given gate bias voltage within the negative temperature-dependence range 516-N, such as at a particular voltage 512 (Vn), the resistance of the compensation transistor 504 decreases as the temperature increases, as indicated by an arrow 520.

Based on the example curves for the temperatures T1, T2, and T3 in the graph 506, whether the compensation transistor 504 operates in the positive temperature-dependence range 516-P or the negative temperature-dependence range 516-N can be changed by changing a gate bias voltage applied to the compensation transistor 504. To cause the compensation transistor 504 to operate in, for example, the negative temperature-dependence range 516-N, any gate bias voltage greater than the range-demarcating gate bias voltage 508 (Vr) may be selected. Further, a particular gate bias voltage above the range-demarcating gate bias voltage 508 (Vr) can be selected to establish a targeted temperature versus resistance relationship.

In other words, a slope of the line in the graph 310 can be determined by selecting a particular gate bias voltage to, for instance, match an inverse slope of the line in the graph 308 (of FIG. 4). Different gate bias voltages establish respective different resistive characteristics 502 that have a different amount of resistance value delta or change per amount of temperature differential. This can facilitate counteracting the positive temperature dependency of the resistive characteristic 402 of the inductor 302 as depicted in the graph 308. Within the negative temperature-dependence range 516-N, gate bias voltages that are relatively closer to the range-demarcating gate bias voltage 508 (Vr) have a smaller resistance delta per temperature differential, which translates to a lesser, flatter slope of the line in the graph 310. On the other hand, gate bias voltages that are relatively farther from the range-demarcating gate bias voltage 508 (Vr) have a larger resistance delta per temperature differential, which translates to a greater, steeper slope of the line in the graph 310.

FIG. 6 illustrates generally at 600 example temperature compensation circuitry 126 that is coupled to the inductive-capacitive tank 320. The temperature compensation circuitry 126 includes a compensation component 304 (CC 304), a compensation component 314 (CC 314), and an example bias circuit 306. In example implementations, each compensation component 304 or 314 is implemented using at least one compensation transistor. As shown, the compensation component 304 is implemented with the compensation transistor 504 (Mp1), and the compensation component 314 is implemented with the compensation transistor 514 (Mp2). Generally, a given implementation of the temperature compensation circuitry 126 may include the compensation component 304 with the compensation transistor 504 coupled to one end of the inductor 302 (e.g., without the compensation transistor 514), may include the compensation component 314 with the compensation transistor 514 coupled to another end of the inductor 302 (e.g., without the compensation transistor 504), or may include both the compensation transistor 504 and the compensation transistor 514 coupled to different ends of the inductor 302.

Each compensation transistor 504 or 514 may be realized using a field effect transistor (FET), such as a p-channel field effect transistor (pFET) or an re-channel FET (nFET) (e.g., a p-channel metal-oxide-semiconductor (PMOS) FET (pMOSFET) or an NMOS FET (nMOSFET)). If implemented as an FET, each compensation transistor 504 or 514 includes a gate terminal and two channel terminals, namely a source terminal and a drain terminal. The type of device—pFET or nFET—used to implement the compensation transistors is a function of the DC bias voltage of the inductor 302 or the transformer 124 (e.g., of FIG. 3) thereof. If the transformer 124 is biased at relatively high voltage (e.g., a non-zero voltage), then pFETs can be used to implement the compensation transistors such that as a gate voltage approaches zero, the resistance of the transistor becomes less as well. On the other hand, if the transformer 124 is biased at zero volts, then nFETs can be used to implement the compensation transistors. In an example of the illustrated circuitry, the transformer 124 is biased at a voltage in the range of 0.8-1.0 V, depending on the device technology.

A wireless signal can propagate through the FET from one channel terminal to another channel terminal. With an example PFET implementation, the drain terminal of the compensation transistor 504 is coupled to the plus node 322 of the inductive-capacitive tank 320. The source terminal of the compensation transistor 504 is coupled to an adjacent component in the receive or transmit chain. With a differential arrangement, the compensation transistor 514 is connected analogously. The drain terminal of the compensation transistor 514 is coupled to the minus node 324 of the inductive-capacitive tank 320. The source terminal of the compensation transistor 514 is coupled to the adjacent component, such as an amplifier (e.g., the amplifier 128).

The compensation transistors 504 and 514 can be operated like switches. For example, the compensation transistors 504 and 514 can be turned off to function like an open switch that terminates the propagation of a wireless signal. This prevents signal propagation along a transmit or receive chain, such as if the corresponding wireless transceiver, or a portion thereof, is to be temporarily inoperative. On the other hand, the compensation transistors 504 and 514 can be turned on to function like a closed switch. In an example broadband architecture implementation as described above, the compensation transistors 504 or 514 can function as pairs of switches (if a differential configuration or as a single switch if a single-ended configuration) that connect or disconnect a respective transformer for a respective frequency band to or from other parts of a receive or transmit chain. Further, while turned on, the compensation transistors 504 and 514 can be biased so as to have a desired effect on a signal propagating through the inductive-capacitive tank 320, as is described below. Thus, the compensation transistor 504 or 514 can provide a switch mechanism for instituting a resistance that varies based on the temperature.

For example, the compensation transistors 504 and 514 can be biased to operate in the positive or the negative temperature-dependence range 516-P or 516-N, as shown in FIG. 5. To do so, a selected gate bias voltage (Vgbias) is applied to a gate terminal of the compensation transistor 504 and another gate terminal of the compensation transistor 514. The gate terminals of the compensation transistors 504 and 514 are coupled to a bias node 602. The bias node 602 forms a part of the bias circuit 306. The bias circuit 306 is described below in terms of biasing the compensation transistor 504 for clarity. However, the principles are also applicable to biasing the compensation transistor 514.

As described above with reference to FIGS. 4 and 5, the inductor 302 has a resistive characteristic 402 with a positive temperature dependency as depicted by the graph 308. To counteract this positive temperature dependency, the compensation transistor 504 is biased such that the resistive characteristic 502 thereof has a negative temperature dependency as depicted by the graph 310. To do so, a gate bias voltage from the negative temperature-dependence range 516-N of the graph 506 is applied to the gate terminal of the compensation transistor 504. In operation, the bias circuit 306 can generate a selected gate bias voltage (Vgbias) at the bias node 602.

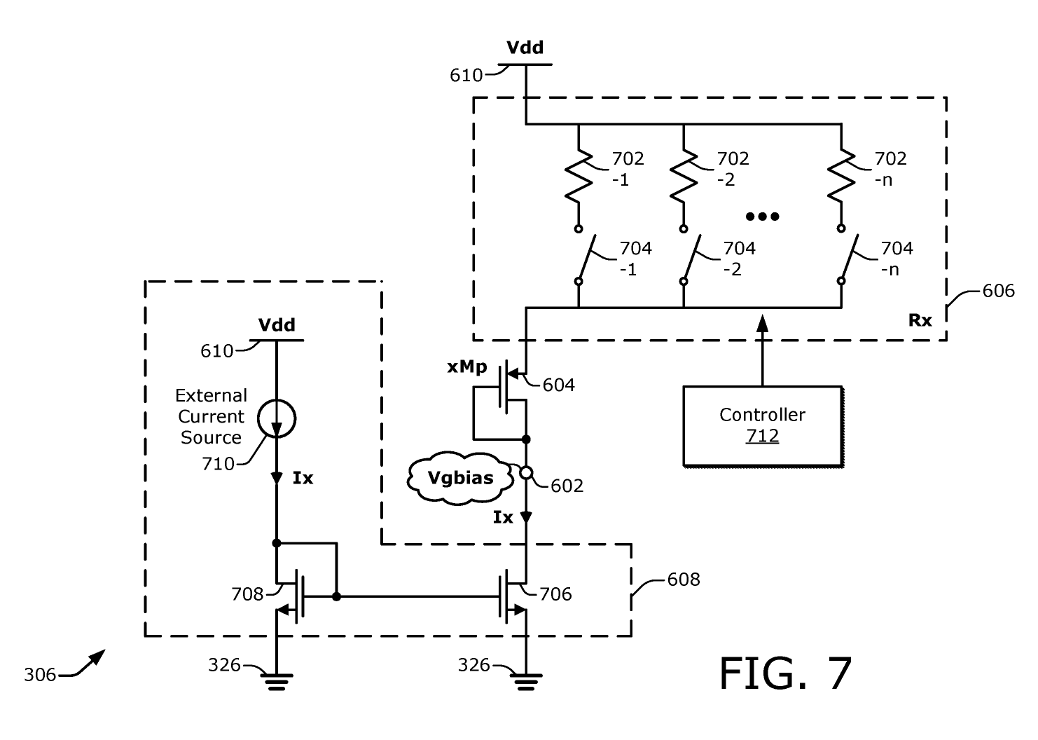

In example implementations, the bias circuit 306 includes a stack of components between a power rail 610 that is held at a supply voltage (Vdd) and the ground node 326. The stack of components is configured to drop a voltage level of the supply voltage (Vdd) down to a selected gate bias voltage (Vgbias) at the bias node 602. Thus, the stacked components can provide a mechanism for generating a gate bias voltage (Vgbias) from a supply voltage (Vdd). The stack of components of the bias circuit 306 includes a resistor 606 (Rx), a bias transistor 604 (xMp), and a current source 608 (Ix). The resistor 606 can be implemented as a variable resistor, and the current source 608 can be implemented with a current mirror. Example implementations that employ a variable resistor with a variable resistance or a current mirror are described below with reference to FIG. 7.

The bias transistor 604 can be implemented with a transistor that comprises a replica of the compensation transistor 504 (Mp1). Thus, if the compensation transistor 504 is implemented as a pFET or as an nFET, the bias transistor 604 is likewise implemented as a pFET or as an nFET, respectively. To replicate a performance of the compensation transistor 504, the bias transistor 604 can have one or more dimensions (e.g., a length or a width) that are proportional to one or more other dimensions of the compensation transistor 504 in accordance with a scaling factor (x). The scaling factor “x” can be any positive value, but it is typically one (1) if the compensation transistor 504 is already small or less than one (1) to enable the bias transistor 604 to occupy less area than the compensation transistor 504 if the compensation transistor 504 is large. If the scaling factor “x” is less than one (e.g., one-half or one-tenth), the current can be scaled down proportionally to maintain an ability to replicate one or more operational characteristics of the compensation transistor 504. By replicating the performance of the compensation transistor 504, the bias transistor 604 can also respond to temperature changes in a manner that is similar or analogous to that of the compensation transistor 504 during operation. For example, the bias transistor 604 can implicitly track the temperature and generate an analog voltage—e.g., the gate bias voltage (Vgbias)—that is a function of the temperature. The temperature compensation circuitry 126 provides this analog voltage to the compensation component 304 and the compensation component 314 to control the respective switches thereof (e.g., the compensation transistor 504 and the compensation transistor 514).

In some implementations, the stack of components are coupled together in series between the power rail 610 and the ground node 326. Thus, the resistor 606, the bias transistor 604, and the current source 608 may be coupled together in series between the power rail 610 and the ground node 326. As shown, the resistor 606 is coupled to the power rail 610, and the current source 608 is coupled to the ground node 326. The bias transistor 604 is coupled between the resistor 606 and the current source 608. The bias node 602 is located between the bias transistor 604 and the current source 608.

The bias transistor 604 can be implemented with, for example, a pMOSFET to match a transistor type of the compensation transistor 504. Thus, the bias transistor 604 includes a gate terminal and two channel terminals—a source terminal and a drain terminal. The source terminal of the bias transistor 604 is coupled to the resistor 606. The drain terminal of the bias transistor 604 is coupled to the current source 608 via the bias node 602. The gate terminal of the bias transistor 604 is coupled to the drain terminal of the bias transistor 604 to configure the bias transistor 604 as a diode-connected transistor. Although not explicitly shown with connecting lines for visual clarity, the gate of the bias transistor 604 is coupled to the gate of the compensation transistor 504 (and the gate of the compensation transistor 514) via the bias node 602. Thus, the gate bias voltage (Vgbias) generated at the bias node 602 is routed and applied to a gate terminal of the compensation transistor 504 to control a biasing of the compensation transistor 504.

To generate the gate bias voltage (Vgbias) at the bias node 602, the components of the bias circuit 306 drop the supply voltage (Vdd) starting from the power rail 610. The current (Ix) is instituted by the current source 608. This current (Ix) at least partially determines a voltage drop across the resistor 606. Thus, the bias circuit 306 generates an intermediate voltage at the source terminal of the bias transistor 604 based on the voltage drop across the resistor 606. The resistor 606 can therefore provide a mechanism for dropping the supply voltage (Vdd) to an intermediate voltage. The bias circuit 306 further generates the gate bias voltage (Vgbias) using another voltage drop across the bias transistor 604, starting from the intermediate voltage at the source terminal of the bias transistor 604. More specifically, the gate bias voltage (Vgbias) at the bias node 602 can be established according to the following equation:

$$Vgbias = Vdd - {I}_{x} {R}_{x } - \sqrt{\frac{2 {I}_{x}}{{K}_{p}}} - {V}_{th} ,$$

where “Vdd” is the supply voltage, “Ix” is the current of the current source 608, “Rx” is the resistance of the resistor 606—which may be variable, “Kp” is the transconductance of the MOSFET-type bias transistor 604, and “Vth” is the threshold voltage of the bias transistor 604. Based on a selected gate bias voltage (Vgbias), a circuit can adjust a current (Ix) instituted by the current source 608 or a variable resistance (Rx) of the resistor 606 to establish the desired gate bias voltage (Vgbias).

Thus, a voltage drop across the bias transistor 604 contributes to the voltage drop between the supply voltage (Vdd) at the power rail 610 and the gate bias voltage (Vgbias) at the bias node 602. The voltage drop across the bias transistor 604 is determined at least partially by the resistance characteristic of the bias transistor 604. This resistance characteristic is based at least partly on the gate bias voltage (Vgbias) that is applied to the gate terminal of the bias transistor 604. Due to the coupling of the drain terminal at the bias node 602 to the gate terminal of the bias transistor 604 to realize a diode-connected transistor configuration, a feedback loop generates a voltage drop across the bias transistor 604 that is temperature dependent.

An example of a feedback control system of the feedback loop is described with reference also to the graph 506 of FIG. 5. Assume that the bias circuit 306 generates an initial gate bias voltage (Vgbias) that places the bias transistor 604 in the negative temperature-dependence range 516-N, such as at the particular voltage 512 (Vn). As an integrated circuit operates and a temperature thereof increases, the resistance of the bias transistor 604 starts to decrease, as shown by the arrow 520. In other words, operational parameters migrate the resistance characteristic to a new temperature curve of the graph 506. As a consequence of the decreasing resistance, the voltage drop across the bias transistor 604 decreases, so the gate bias voltage (Vgbias) at the bias node 602 starts to increase. The increasing gate bias voltage (Vgbias) is fed back to the gate of the bias transistor 604. This increasing gate bias voltage (Vgbias) causes the resistance to start increasing by moving the operating point up a given temperature curve. Thus, the bias transistor 604, in conjunction with the feedback loop between the drain and gate terminals of the diode-connected transistor, can provide a feedback mechanism for dropping the intermediate voltage to the gate bias voltage (Vgbias) based on the temperature.

By establishing this feedback effect, the voltage drop across the bias transistor 604 is stabilized and so is the gate bias voltage (Vgbias) at the bias node 602, which voltage is also routed to a gate terminal of the compensation transistor 504. Because the compensation transistor 504 and the bias transistor 604 have comparable operational characteristics, including across temperature changes, a desired negative temperature dependency can be created for the compensation component 304, which counteracts the positive temperature dependency of the inductor 302. Although particular transistor types (e.g., n-type or MOSFET) are illustrated in the accompanying drawings and described herein, other types of transistors may alternatively be implemented. Further, the various circuit components may be interconnected in different manners.

FIG. 7 illustrates another example bias circuit 306 that is similar to the one of FIG. 6. However, the bias circuit 306 in FIG. 7 depicts example implementations for the resistor 606 and the current source 608. In this bias circuit 306, the resistor 606 is implemented as a variable resistor or a resistive component configured to have an adjustable resistance value (Rx), and the current source 608 is implemented using a current mirror to provide the current (Ix). As shown, the resistor 606 includes multiple resistors 702-1, 702-2 . . . 702-n, with “n” representing some integer greater than one. The multiple resistors 702-1 . . . 702-n are coupled together in parallel between the power rail 610 and the source terminal of the bias transistor 604. Each respective resistor 702 is coupled in series with a respective switch 704 of multiple switches 704-1, 704-2 . . . 704-n. Each switch 704 can be implemented using, for instance, a transistor.

In example operations, a controller 712 can open or close a switch 704 (e.g., turn off or turn on, respectively, a corresponding transistor) to deactivate or activate, respectively, a given resistor 702 to contribute a resistance to the resistance (Rx) of the resistor 606. Thus, a voltage drop between the supply voltage (Vdd) and an intermediate voltage at the source terminal of the bias transistor 604 can be adjusted by controlling the multiple switches 704-1 . . . 704-n using the controller 712. Although the multiple resistors 702-1 . . . 702-n are described as being coupled together in parallel, other circuit arrangements may alternatively be implemented. For example, the multiple resistors 702-1 . . . 702-n may be coupled together in series with each respective switch 704 coupled in parallel to a respective resistor 702 to short or deactivate the resistor 702 if closed.

To institute the current (Ix), the current source 608 may use a current mirror including a transistor 706 and a transistor 708. Here, the transistor 706 and the transistor 708 are implemented as n-type MOS (NMOS) transistors. The transistor 708 is coupled in series with an external current source 710 between the power rail 610 that is held at the supply voltage (Vdd) and the ground node 326. A drain terminal of the transistor 708 is coupled to the external current source 710, and a source terminal of the transistor 708 is coupled to the ground node 326. The external current source 710 generates a current flow (Ix) through the transistor 708 in the path between the power rail 610 and the ground node 326.

As part of the current mirror configuration, the drain terminal of the transistor 708 is coupled to the gate terminal of the transistor 708. Further, the gate terminal of the transistor 708 is also coupled to a gate terminal of the transistor 706. A drain terminal of the transistor 706 is coupled to the bias node 602, and a source terminal of the transistor 706 is coupled to the ground node 326. Thus, both the transistor 708 and the transistor 706 are positioned along paths that extend between the power rail 610 and the ground node 326. Also, the gate and drain terminals of the transistor 708 are coupled together to implement a diode-connected transistor. Additionally, the gate terminals of the transistors 706 and 708 are coupled together, and the source terminals of the transistors 706 and 708 are coupled together. Consequently, the current (Ix) flowing through the transistor 708 is mirrored over to the transistor 706, which institutes the current (Ix) through the resistor 606 and the bias transistor 604.

FIG. 8 illustrates an example capacitor 316 that includes temperature compensation circuitry 126 (TCC). The capacitor 316 can be incorporated into an inductive-capacitive tank 320 (LC Tank 320) as part of a transformer 124 (both of FIG. 3). As shown, the capacitor 316 is implemented as a variable capacitor that can be adjusted to have various capacitance values using multiple capacitors. For differential signaling purposes, the capacitor 316 includes multiple plus capacitors 802-1, 802-2 . . . 802-(n−1), 802-n and multiple minus capacitors 804-1, 804-2 . . . 804-(n−1), 804-n, with representing some positive integer greater than one. The multiple plus capacitors 802-1 . . . 802-n are coupled in parallel with each other between the plus node 322 and the temperature compensation circuitry 126. The multiple minus capacitors 804-1 . . . 804-n are coupled in parallel with each between the temperature compensation circuitry 126 and the minus node 324. Respective pairs of plus capacitors 802-1 to 802-n and minus capacitors 804-1 to 804-n (e.g., the plus capacitor 802-1 and the minus capacitor 804-1 form a capacitor pair) are coupled in series with each other along respective parallel branches extending between the plus node 322 and the minus node 324.

In some implementations, the temperature compensation circuitry 126 includes multiple compensation components 304-1, 304-2 . . . 304-(n−1), 304-n and at least one bias circuit 306. A respective compensation component 304 is implemented for each respective pair of plus and minus capacitors 802-1 . . . 802-n and 804-1 . . . 804-n. The pairs of plus and minus capacitors are then coupled in parallel with each other, along with a respective compensation component 304, between the plus node 322 and the minus node 324. For example, the plus capacitor 802-2, the compensation component 304-2, and the minus capacitor 804-2 are coupled together in series between the plus node 322 and the minus node 324. The plus capacitor 802-2 is coupled to the plus node 322, and the minus capacitor 804-2 is coupled to the minus node 324. The compensation component 304-2 is coupled between the plus and minus capacitors 802-2 and 804-2.

The bias circuit 306 is configured to control each of the multiple compensation components 304-1, 304-2 . . . 304-(n−1), and 304-n. Each compensation component 304 can be implemented with, for instance, a compensation transistor 504. For instance, the compensation component 304-1 is depicted as including a compensation transistor 504-1. By selectively turning the compensation transistors on or off, different capacitive branches can be activated or deactivated with regard to contributing a capacitive value to the variable capacitive value of the capacitor 316. Although the variable capacitor 316 is shown being implemented using capacitors that are coupled together in parallel, other circuit arrangements may alternatively be implemented. For example, the capacitors may be coupled together in series with switches coupled in parallel with individual capacitors to selectively short, and thus deactivate, the capacitors. Further, some combination of parallel and series connections may be implemented.

Operational performance of the multiple plus capacitors 802-1 . . . 802-n and the multiple minus capacitors 804-1 . . . 804-n can be temperature dependent. To counteract this temperature dependency, the bias circuit 306 can bias each respective compensation component 304 of the multiple compensation components 304-1 . . . 304-n into the positive temperature-dependence range 516-P or the negative temperature-dependence range 516-N (of FIG. 5). If, for instance, the multiple plus capacitors 802-1 . . . 802-n and the multiple minus capacitors 804-1 . . . 804-n are configured to have a positive temperature dependency, the bias circuit 306 can apply a gate bias voltage (Vgbias) selected to operate the multiple compensation components 304-1 . . . 304-n in the negative temperature-dependence range 516-N to counteract the temperature dependency.

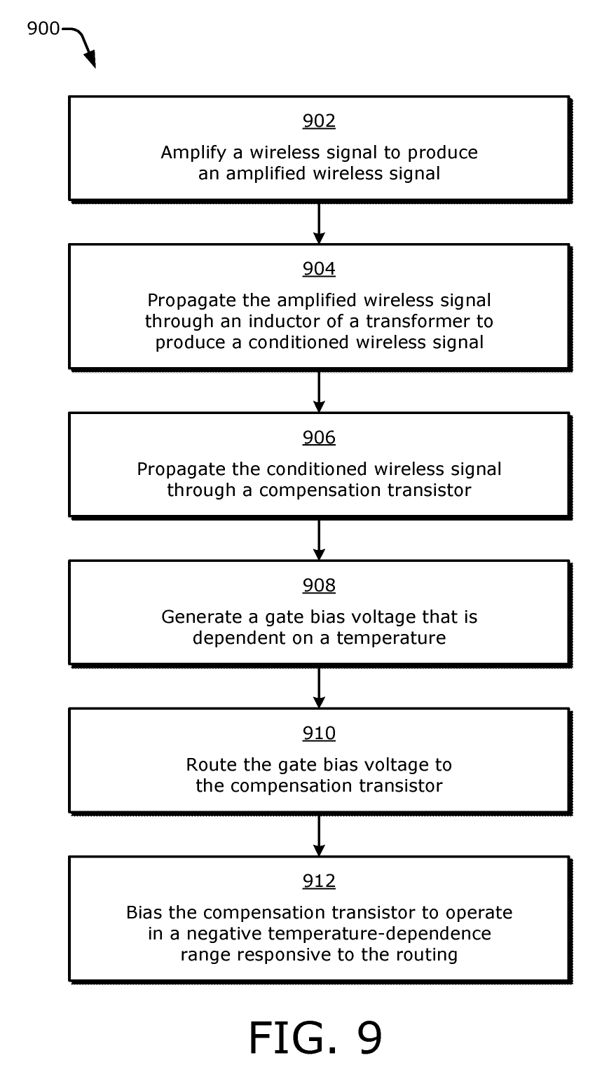

FIG. 9 is a flow diagram illustrating an example process 900 for temperature dependency compensation. The process 900 is described in the form of a set of blocks 902-912 that specify operations that can be performed. However, operations are not necessarily limited to the order shown in FIG. 9 or described herein, for the operations may be implemented in alternative orders or in fully or partially overlapping manners. Operations represented by the illustrated blocks of the process 900 may be performed by a wireless transceiver 120 (e.g., of FIG. 1 or 2). More specifically, the operations of the process 900 may be performed by a receive chain 202 or a transmit chain 204, including by a transformer 124 and temperature compensation circuitry 126 as illustrated in FIGS. 2 and 3.

At block 902, a wireless signal is amplified to produce an amplified wireless signal. For example, an amplifier (e.g., an amplifier 122 or an amplifier 128) can amplify a wireless signal 210 to produce an amplified wireless signal 210. The amplifier may comprise a low-noise amplifier (LNA) of a receive chain 202 or a power amplifier (PA) of a transmit chain 204.

At block 904, the amplified wireless signal is propagated through an inductor of a transformer to produce a conditioned wireless signal. For example, the receive chain 202 or the transmit chain 204 can propagate the amplified wireless signal 210 through an inductor 302 or 312 of a transformer 124 to produce a conditioned wireless signal 210. The transformer 124 may condition the wireless signal 210 by altering a voltage of the signal, tuning the signal using an inductive-capacitive tank, transforming the signal from single-ended to differential (or vice versa), and so forth.

At block 906, the conditioned wireless signal is propagated through a compensation transistor. For example, the receive chain 202 or the transmit chain 204 can propagate the conditioned wireless signal 210 through a compensation transistor 504 or 514. With the compensation transistor 504 or 514 turned on, signals may propagate between two channel terminals of the transistor, such as between a drain terminal and a source terminal thereof. The compensation transistor 504 or 514 may comprise a compensation component 304 that forms a part of the temperature compensation circuitry 126.

At block 908, a gate bias voltage that is dependent on a temperature is generated. For example, a bias circuit 306 can generate a gate bias voltage (Vgbias) that is dependent on a temperature. To do so, a bias transistor 604 may be operated in a diode-connected configuration in which a gate terminal and a drain terminal thereof are coupled to a bias node 602, which provides the gate bias voltage (Vgbias). The diode-connected configuration provides a feedback control that operates at least partially responsive to the operational temperature.

At block 910, the gate bias voltage is routed to the compensation transistor. For example, an electrical connection or metal wire can route the gate bias voltage (Vgbias) to the compensation transistor 504 or 514. The bias transistor 604 and the compensation component 304 may be located proximate to each other so that each experiences a similar temperature during operation and so that a length of a wire is reduced between the bias node 602 and the compensation transistor 504 or 514.

At block 912, the compensation transistor is biased to operate in a negative temperature-dependence range responsive to the routing. For example, application of the gate bias voltage (Vgbias) to the compensation transistor 504 or 514 can cause the compensation transistor 504 or 514 to operate in a negative temperature-dependence range 516-N responsive to a voltage level of the gate bias voltage (Vgbias). To do so, a resistance value of an adjustable resistor 606 of the bias circuit 306 may be adjusted so that a voltage drop across the resistor 606 causes the gate bias voltage (Vgbias) to be greater than a range-demarcating gate bias voltage 508 (Vr).

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Further, items represented in the accompanying figures and terms discussed herein may be indicative of one or more items or terms, and thus reference may be made interchangeably to single or plural forms of the items and terms in this written description. Finally, although subject matter has been described in language specific to structural features or methodological operations, it is to be understood that the subject matter defined in the appended claims is not necessarily limited to the specific features or operations described above, including not necessarily being limited to the organizations in which features are arranged or the orders in which operations are performed.

What is claimed is:

1. An apparatus comprising:
an amplifier configured to amplify a wireless signal to produce an amplified wireless signal;
a transformer coupled to the amplifier and configured to condition the amplified wireless signal, the transformer including an inductor;
a compensation component coupled in series with the inductor, the compensation component including a compensation transistor that is configured to operate in at least one of a positive temperature-dependence range or a negative temperature-dependence range; and
a bias circuit including a bias node, the bias node coupled to the compensation transistor, the bias circuit configured to cause the compensation transistor to operate in the positive temperature-dependence range or the negative temperature-dependence range.

2. The apparatus of claim 1, wherein:
the inductor has a resistive characteristic that has a positive temperature dependency; and
the compensation transistor is configured to counteract the positive temperature dependency of the resistive characteristic of the inductor by operating in the negative temperature-dependence range.

3. The apparatus of claim 2, wherein:
the bias circuit is configured to generate a gate bias voltage at the bias node to cause the compensation transistor to operate in the negative temperature-dependence range.

4. The apparatus of claim 3, wherein:
the bias circuit includes a bias transistor that is coupled to the bias node; and
the bias circuit is configured to generate the gate bias voltage at the bias node using the bias transistor and based on a temperature.

5. The apparatus of claim 4, wherein:
the bias circuit includes a resistor and a current source that are coupled in series with the bias transistor; and
the bias circuit is configured to generate the gate bias voltage based on a voltage drop across the resistor and another voltage drop across the bias transistor.

6. The apparatus of claim 1, wherein:
the bias circuit includes a bias transistor that is coupled to the bias node, the bias transistor comprising a replica of the compensation transistor.

7. The apparatus of claim 6, wherein one or more dimensions of the bias transistor are proportional to one or more other dimensions of the compensation transistor in accordance with a scaling factor.

8. The apparatus of claim 1, wherein:
the compensation transistor includes a resistance that is configured to vary based on a temperature; and
the bias circuit is configured to use the bias node to cause the resistance of the compensation transistor to vary over a range based on the temperature.

9. The apparatus of claim 1, wherein:
the positive temperature-dependence range of the compensation transistor corresponds to a resistive characteristic of the compensation transistor being configured to increase as a temperature increases; and
the negative temperature-dependence range of the compensation transistor corresponds to the resistive characteristic of the compensation transistor being configured to decrease as the temperature increases.

10. The apparatus of claim 1, further comprising:
a capacitor coupled in parallel with the inductor of the transformer, wherein:
the capacitor includes a capacitive component, another compensation component coupled in series with the capacitive component, and another bias circuit coupled to the other compensation component;
the capacitive component has a characteristic that is temperature dependent; and
the other bias circuit is configured to bias the other compensation component to counteract the characteristic of the capacitive component that is temperature dependent.

11. A wireless transceiver with temperature dependency compensation, the wireless transceiver comprising:
a transformer including an inductor having a first terminal;
a compensation transistor coupled in series with the inductor via the first terminal, the compensation transistor including a gate terminal; and
a bias circuit coupled to the gate terminal of the compensation transistor, the bias circuit including:
a resistor coupled to a power rail;
a bias transistor coupled to the resistor;
a current source coupled to the bias transistor; and
a bias node coupled to the gate terminal of the compensation transistor.

12. The wireless transceiver of claim 11, wherein:
the inductor has a resistive characteristic that has a positive dependence on a temperature; and
the compensation transistor is configured to produce a resistive characteristic that has a negative dependence on the temperature.

13. The wireless transceiver of claim 12, wherein the bias circuit is configured to generate a gate bias voltage at the bias node to cause the compensation transistor to operate in a negative temperature-dependence range.

14. The wireless transceiver of claim 11, wherein:
the resistor, the bias transistor, and the current source are coupled together in series between the power rail and a ground node; and
the bias node is coupled to at least one terminal of the bias transistor.

15. The wireless transceiver of claim 14, wherein:
the resistor comprises a resistive component having a variable resistance; and
the current source comprises a current mirror.

16. The wireless transceiver of claim 14, wherein the at least one terminal of the bias transistor comprises a channel terminal and a gate terminal of the bias transistor.

17. The wireless transceiver of claim 11, wherein the compensation transistor is configured to institute a resistance that varies based on a temperature.

18. The wireless transceiver of claim 11, further comprising:
another compensation transistor coupled in series with the inductor via a second terminal of the inductor, the other compensation transistor including another gate terminal,
wherein the bias node is coupled to the other gate terminal of the other compensation transistor.

19. The wireless transceiver of claim 11, further comprising:
a capacitor coupled in parallel with the inductor via the first terminal and a second terminal of the inductor;
at least one other compensation transistor coupled to the capacitor, the at least one other compensation transistor including at least one other gate terminal; and
another bias circuit coupled to the at least one other gate terminal of the at least one other compensation transistor.

20. The wireless transceiver of claim 19, wherein:
the capacitor comprises a capacitive component having a variable capacitance, the capacitive component including multiple capacitors;
the at least one other compensation transistor comprises multiple other compensation transistors; and
respective ones of the multiple other compensation transistors are coupled in series with respective ones of the multiple capacitors.

21. A system comprising:
an amplifier;
a transformer coupled to the amplifier, the transformer including an inductor having a temperature-dependent resistive characteristic;
compensation means for counteracting the temperature-dependent resistive characteristic of the inductor, the compensation means coupled to the inductor; and
bias means for biasing the compensation means based on a temperature, the bias means coupled to the compensation means.

22. The system of claim 21, wherein the compensation means comprises switch means for instituting a resistance that varies based on the temperature.

23. The system of claim 22, wherein:
the bias means comprises stacked means for generating a gate bias voltage from a supply voltage; and
the system is configured to route the gate bias voltage to the compensation means.

24. The system of claim 23, wherein the stacked means comprises resistance means for dropping the supply voltage to an intermediate voltage.

25. A method for compensating for a temperature dependency of a circuit, the method comprising:
amplifying a wireless signal to produce an amplified wireless signal;
propagating the amplified wireless signal through an inductor of a transformer to produce a conditioned wireless signal;
propagating the conditioned wireless signal through a compensation transistor;
generating a gate bias voltage that is dependent on a temperature;
routing the gate bias voltage to the compensation transistor; and
biasing the compensation transistor to operate in a negative temperature-dependence range responsive to the routing.

26. The method of claim 25, wherein:
the propagating the amplified wireless signal through the inductor comprises changing a resistive characteristic of the inductor responsive to a positive dependency on the temperature; and
the propagating the conditioned wireless signal through the compensation transistor comprises changing a resistive characteristic of the compensation transistor responsive to a negative dependency on the temperature in accordance with the biasing.

27. The method of claim 25, wherein the routing comprises applying the gate bias voltage to a gate terminal of the compensation transistor.

28. The method of claim 27, further comprising:
turning off the compensation transistor to terminate the propagating of the conditioned wireless signal through the compensation transistor.

29. The method of claim 25, wherein the biasing comprises causing the compensation transistor to decrease a resistive characteristic of the compensation transistor responsive to an increase in the temperature.

30. The method of claim 25, wherein the generating comprises establishing a feedback loop that produces the gate bias voltage in dependence on the temperature.
